(19) United States
(12) Patent Application Publication
(10) Pub. No.: US 2024/0431212 A1
(43) Pub. Date: Dec. 26, 2024

(54) ROBUST BULK ACOUSTIC WAVE RESONATOR CAPACITOR

(71) Applicant: Skyworks Global Pte. Ltd., Singapore (SG)

(72) Inventors: Benjamin Paul Abbott, Irvine, CA (US); Mihir Shailesh Patel, Hopkinton, MA (US); Tomoya Komatsu, Irvine, CA (US); Alexandre Augusto Shirakawa, Cardiff by the Sea, CA (US); Kwang Jae Shin, Yongin (KR)

(21) Appl. No.: 18/750,888

(22) Filed: Jun. 21, 2024

Related U.S. Application Data
(60) Provisional application No. 63/523,000, filed on Jun. 23, 2023.

(51) Int. Cl. H10N 30/87; H01G 4/228; H03H 9/54; H03H 9/56

(52) U.S. Cl. CPC H10N 30/87; H01G 4/228; H03H 9/542; H03H 9/568

(57) ABSTRACT

A bulk acoustic wave resonator configured as a capacitor has a piezoelectric structure including a mesa region suspended above a substrate to define a cavity. The piezoelectric structure includes a perimeter region surrounding a perimeter of the mesa region with a sloping portion that gradually slopes towards the substrate and a connecting portion proximate the substrate that supports the piezoelectric structure with respect to the substrate. The piezoelectric structure incudes a bottom electrode layer, a top electrode layer, and a piezoelectric layer therebetween. An overlapping region where the bottom electrode layer and the top electrode layer overlap extends across at least a width of the mesa region between opposing sides of the perimeter region.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The present disclosure relates to relates to a capacitor having a reduced perimeter stress, and, in particular, a bulk acoustic wave (BAW) resonator having an improved performance due to the integration of the capacitor.

### Description of the Related Technology

BAW resonators are a type of acoustic device used in a number of applications including radiofrequency (RF) modules for wireless devices, such as RF filters.

Resonator capacitors can improve performance of BAW filters and may be constructed by adding extra metal to the top of a BAW resonator stack, and creating a capacitive connection between the top and bottom electrode.

### SUMMARY OF CERTAIN INVENTIVE CONCEPTS

The systems, methods and devices of this disclosure each have several aspects, no single one of which is solely responsible for the desirable attributes disclosed herein.

To address the above-mentioned problems certain embodiments include a reduced width of a mesa air cavity resulting in an increase of the average stack thickness along the perimeter of the capacitor, essentially without modifying the deposition process for the BAW resonator stack's layers.

In some aspects, the techniques described herein relate to a capacitor including: a substrate; and a piezoelectric structure including a piezoelectric structure including a cavity above the substrate and a mesa region suspended above the cavity, the piezoelectric structure further including a perimeter region surrounding a perimeter of the mesa region, the perimeter region including a sloping portion that gradually slopes towards the substrate and a connecting portion proximate the substrate that supports the piezoelectric structure with respect to the substrate, the piezoelectric structure including a bottom electrode layer, a top electrode layer, and a piezoelectric layer therebetween, an overlapping region where the bottom electrode layer and the top electrode layer overlap extending across at least a width of the mesa region between opposing sides of the perimeter region.

In some aspects, the techniques described herein relate to a capacitor wherein the overlapping region further extends across at least a portion of the sloping portion of the perimeter region.

In some aspects, the techniques described herein relate to a capacitor wherein the overlapping region extends across at least 25% of the width of the sloping portion on a first side of the capacitor having a bottom electrode contact, the first side opposing a second side of the capacitor having a top electrode contact.

In some aspects, the techniques described herein relate to a capacitor wherein the overlapping region extends across an entire width of the sloping portion on the first side.

In some aspects, the techniques described herein relate to a capacitor wherein the overlapping region extends across at least a portion of a width of the connecting portion.

In some aspects, the techniques described herein relate to a capacitor wherein the overlapping region extends across an entire width of the sloping portion on a first side of the capacitor having a bottom electrode contact, the first side opposing a second side of the capacitor having a top electrode contact, and further extends across at least a portion of the connecting portion on the first side of the capacitor.

In some aspects, the techniques described herein relate to a capacitor wherein the bottom electrode layer extends under an entire area of the sloping portion.

In some aspects, the techniques described herein relate to a capacitor wherein the top electrode layer extends across at least 75% of an area of the sloping portion.

In some aspects, the techniques described herein relate to a capacitor wherein the top electrode layer extends across an entire area of the sloping portion.

In some aspects, the techniques described herein relate to a capacitor wherein the bottom electrode layer extends across at least 75% of an area of the sloping portion.

In some aspects, the techniques described herein relate to a capacitor wherein the bottom electrode layer extends across an entire area of the sloping portion.

In some aspects, the techniques described herein relate to a capacitor further including a silicon dioxide layer between the substrate and the piezoelectric structure.

In some aspects, the techniques described herein relate to a bulk acoustic wave resonator including the capacitor.

In some aspects, the techniques described herein relate to a radio frequency filter including: an input port and an output port; and a plurality of bulk acoustic wave resonators connected between the input port and the output port and arranged to generate a filter response, at least one of the plurality of bulk acoustic wave resonators configured as a capacitor having a piezoelectric structure including a cavity above a substrate and a mesa region suspended above the cavity, the piezoelectric structure further including a perimeter region surrounding a perimeter of the mesa region, the perimeter region including a sloping portion that gradually slopes towards the substrate and a connecting portion proximate the substrate that supports the piezoelectric structure with respect to the substrate, the piezoelectric structure including a bottom electrode layer, a top electrode layer, and a piezoelectric layer therebetween, an overlapping region where the bottom electrode layer and the top electrode layer overlap extending across at least a width of the mesa region between opposing sides of the perimeter region.

In some aspects, the techniques described herein relate to a capacitor wherein the overlapping region extends across at least 25% of the width of the sloping portion on a first side of the capacitor having a bottom electrode contact, the first side opposing a second side of the capacitor having a top electrode contact.

In some aspects, the techniques described herein relate to a capacitor wherein the overlapping region extends across an entire width of the sloping portion on the first side.

In some aspects, the techniques described herein relate to a capacitor wherein the overlapping region extends across at least a portion of a width of the connecting portion.

In some aspects, the techniques described herein relate to a capacitor wherein the overlapping region extends across an entire width of the sloping portion on a first side of the capacitor having a bottom electrode contact, the first side opposing a second side of the capacitor having a top electrode contact, and further extends across at least a portion of the connecting portion on the first side of the capacitor.

In some aspects, the techniques described herein relate to a radio frequency module including: one or more amplifiers configured to amplify a radio frequency signal; and a radio frequency filter including a plurality of bulk acoustic wave resonators, at least one of the plurality of bulk acoustic wave resonators configured as a capacitor having a piezoelectric structure including a cavity above a substrate and a mesa region suspended above the cavity, the piezoelectric structure further including a perimeter region surrounding a perimeter of the mesa region, the perimeter region including a sloping portion that gradually slopes towards the substrate and a connecting portion proximate the substrate that supports the piezoelectric structure with respect to the substrate, the piezoelectric structure including a bottom electrode layer, a top electrode layer, and a piezoelectric layer therebetween, an overlapping region where the bottom electrode layer and the top electrode layer overlap extending across at least a width of the mesa region between opposing sides of the perimeter region.

In some aspects, the techniques described herein relate to a wireless device including the radio frequency module.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure.

FIG. 1 is a schematic cross sectional side view of a bulk acoustic wave (BAW) resonator.

FIG. 2 is a graph showing a frequency response of a BAW resonator.

FIG. 3 shows a filter according to aspects of the present invention.

FIG. 4 illustrates schematically the frequency responses of the BAW resonators and the passband of the filter shown in FIG. 3.

FIG. 5 illustrates schematically a cross section of a stack of a substrate and a membrane of a capacitor in a relaxed state and in a stressed state.

FIG. 6 illustrates the stress distribution in an xy-plane of a capacitor having an essentially or generally oval shape and a capacitor having an essentially or a generally circular shape as obtained from a first principle simulation.

FIG. 7 illustrates the stress distribution in an xz-plane for specific values of the y coordinate of the capacitor having the essentially or generally oval shape of FIG. 6.

FIG. 8 illustrates the stress distribution in an xz-plane for different widths of a cavity of a capacitor having an essentially or a generally oval shape and the corresponding stress distribution in a z-direction at the wafer center.

FIGS. 9A-9B illustrate embodiments of a capacitor with improved structural rigidity.

FIG. 10 illustrates a filter according to an embodiment.

FIG. 11 illustrates a radio-frequency front end module according to an embodiment.

### DETAILED DESCRIPTION OF EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Aspects and embodiments described herein are directed to one or more bulk acoustic wave (BAW) resonators of a filter having an improved performance due to the integration of a capacitor into the filter.

BAW resonator capacitors can have relatively large tensile stresses on the perimeter of the resonator capacitors. The tensile stress may result in a crack or tear in the BAW resonator stack. Some solutions control the tensile stress by modifying the deposition process for the stack's layers in the production process or the process of records (POR). But this can be costly.

It is cost effective to construct the capacitor using an existing resonator fabrication process. A fabrication process optimized to produce a rugged resonator can, however, result in weak capacitors.

Aspects and embodiments described herein are directed to one or more capacitors having a reduced width of a mesa air cavity resulting in more robust capacitors due to an increase of an average stack thickness and/or structural rigidity along the perimeter of the capacitor, essentially without modifying the deposition process for the layers of the stack.

A BAW resonator is a form of acoustic wave resonator that includes a layer of piezoelectric material positioned or sandwiched between a top and a bottom electrode and suspended over a cavity that allows for the layer of piezoelectric material to vibrate. A signal applied across the top and bottom electrodes causes an acoustic wave to be generated in and travel through the layer of piezoelectric material. A BAW resonator exhibits a frequency response to applied signals with a resonance peak based at least in part on a thickness of the film of piezoelectric material. The primary acoustic wave generated in a BAW resonator is an acoustic wave that travels through the layer of piezoelectric material in a direction generally perpendicular to layers of conducting material forming the top and bottom electrodes of the BAW resonator.

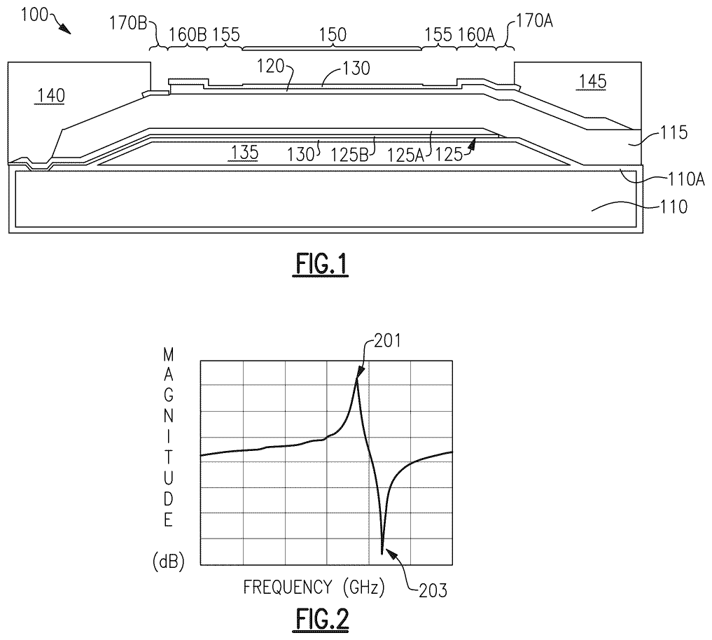

FIG. 1 is a schematic cross-sectional side view of an example of a BAW resonator 100. The BAW resonator 100 may be configured as a capacitor for example. The BAW resonator 100 is disposed on a substrate 110, for example, a silicon substrate that may include a dielectric surface layer 110A, which can include silicon dioxide. The BAW resonator 100 includes a layer or film of piezoelectric material 115, for example, aluminum nitride (AlN). A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a seed layer 125B, for example of titanium (Ti), disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a passivation layer of dielectric material 130. The dielectric material 130 can include silicon dioxide, as an example.

The resonator 100 may be configured as a capacitor, for example, where the top electrode 120 covers a relatively large area and forms a corresponding relatively large overlapping area with the bottom electrode 125, thereby creating a capacitor.

A cavity 135 is defined beneath the layer of dielectric material 130 covering the bottom electrode 125 and the surface layer 110A of the substrate 110. In the illustrated embodiment, the cavity 135 is an air cavity. A bottom electrical contact 140 formed of, for example, copper may make electrical connection with the bottom electrode 125. As shown, the bottom electrode 125 extends from the edge of the cavity 135 that supports the bottom electrode contact 140 (left side in illustrated cross-section) of the resonator 100 from beyond the edge of the cavity 135, across the underside of the piezo electric material 115 (left to right in the illustration), but does not extend all the way across the width of the cavity 135. Rather, the bottom electrode 125 stops short of the far edge of the cavity 135, prior to where the piezoelectric material 115 starts to slope downwards towards the substrate 110. A top electrical contact 145 formed of, for example, copper may make electrical connection with the top electrode 120. As shown, the top electrode 120 extends from the edge of the cavity 135 that supports the top electrode contact 145 (right side in illustrated cross-section) of the resonator 100 from beyond the edge of the cavity 135 and across the underside of the piezo electric material 115 (right to left in the illustration), but does not extend all the way across the width of the cavity 135. Rather, like the bottom electrode 125, the top electrode 120 stops short of the far edge of the cavity 135, prior to where the piezoelectric material 115 starts to slope downwards towards the substrate 110.

The BAW resonator 100 may include a central region 150 including a main active domain in the layer or film of piezoelectric material 115 in which a main acoustic wave is excited during operation. Recessed frame regions 155 may bound and define the lateral extent of the central region 150. The recessed frame regions 155 may be defined by areas that have a thinner layer of dielectric material 130 on top of the top electrode 120 than in the central region 150. The layer of dielectric material 130 in the recessed frame regions 155 may be from about 10 nm to about 100 nm thinner than the layer of dielectric material 130 in the central region 150 and/or the difference in thickness of the dielectric material in the recessed frame regions 155 vs. in the central region 150 may cause the resonant frequency of the device in the recessed frame regions 155 to be between about 5 MHz to about 50 MHz higher than the resonant frequency of the device in the central region 150.

A raised frame region 160A, 160B may be defined on opposite sides of the recessed frame regions 155 from the central region 150 and may directly abut the outside edges of the recessed frame regions 155. The raised frame regions 160A, 160B may be defined by areas where the top electrode 120 is thicker than in the central region 150 and in the recessed frame regions 155. The top electrode 120 may have the same thickness in the central region 150 and in the recessed frame regions 155 but a greater thickness in the raised frame regions 160A, 160B. The top electrode 120 may be between about 50 nm and about 500 nm thicker in the raised frame regions 160A, 160B than in the central region 150 and/or in the recessed frame regions 155. The raised frame regions 160A, 160B may be, for example, 1 μm or more in width, or 4 μm or more in width.

Beyond the raised frame region 160B, on an opposite side to the central region 150, on one side of the BAW resonator is an outer region 170B. The top electrode 120 terminates at the boundary between the raised frame region 160B and the outer region 170B, such that the top electrode 120 does not extend into the outer region 170B. Another outer region 170A is disposed at the opposite side of the BAW resonator from outer region 170B. In this outer region 170A, the top electrode 120 continues from the raised frame region 160A (without changing thickness), whereas the bottom electrode 125 terminates.

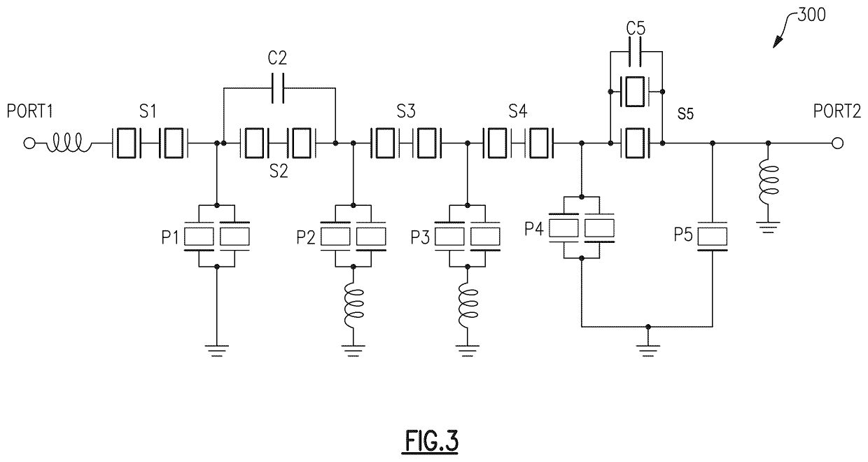

FIG. 2 illustrates schematically a frequency response of a typical BAW resonator, such as the BAW resonator described with respect to FIG. 1. It can be seen in FIG. 2 that the BAW resonator displays a resonance 201 and an anti-resonance 203 at nearby frequencies.

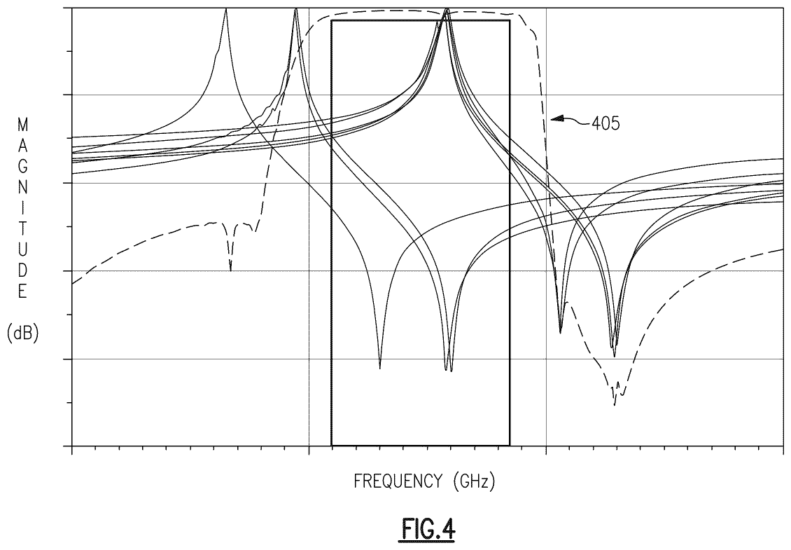

FIG. 3 shows a filter 300 according to aspects of the present invention. The filter network 300 may comprise one or a plurality of BAW resonators. In the example illustrated in FIG. 3, the filter 300 is a passband or ladder filter, though it will be appreciated that the BAW resonators described herein can be included in other types of filters.

The exemplary ladder filter 300 includes a plurality of series resonators S1, S2, S3, S4, and S5 coupled in series between an input port, PORT1, and an output port, PORT2. The filter 300 also includes a plurality of parallel resonators P1, P2, P3, P4, and P5 connected between terminals of the series resonators and ground, optionally trough an inductor. Whilst five groups of series resonators S1, S2, S3, S4, S5 and five groups of parallel resonators P1, P2, P3, P4, P5 are shown, it will be appreciated that more or fewer series and/or parallel resonators may be used.

The exemplary ladder filter 300 includes a plurality of capacitors C2, and C5 coupled in parallel to the series resonators S2 and S5, respectively. Whilst two parallel capacitors C2, C5 are shown, it will be appreciated that more or fewer capacitors may be used.

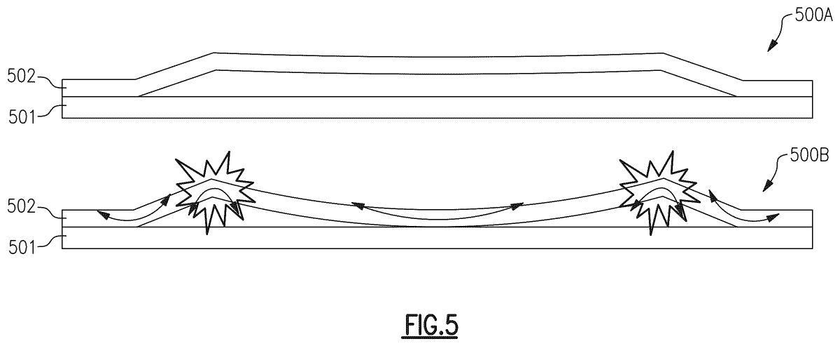

FIG. 4 illustrates schematically the frequency responses (solid lines) of the BAW resonators and the passband 405 (dashed lines) of the filter 300 shown in FIG. 3. The capacitors C2, C5 may be utilized to steepen the critical right skirt of the passband 405.

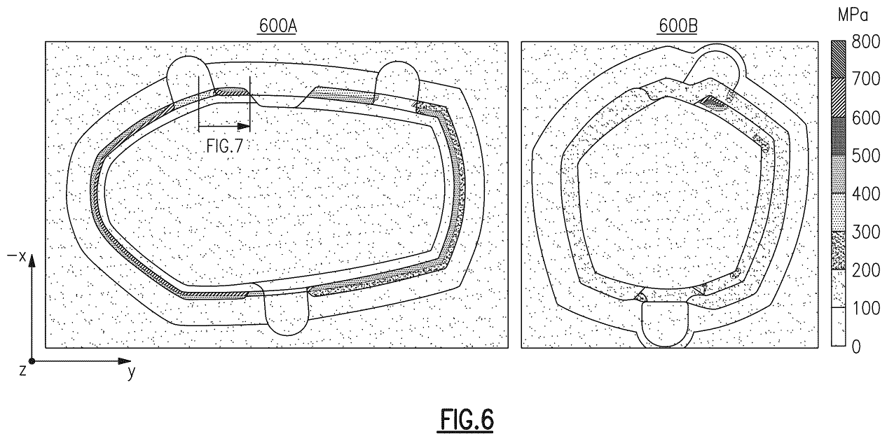

FIG. 5 illustrates schematically a cross section of a stack of a substrate 501 and a membrane 502 of a capacitor in a relaxed state 500A and in a stressed state 500B. The piezoelectric of the membrane 502 may be tensile in the lateral plane. This can result in the columnar structure of the piezoelectric at the perimeter of the capacitor to tear. The membrane 502 may deflect downward and place a strong bending moment on the perimeter of the resonator. The stress at the perimeter of the capacitor is particularly sensitive to the shape of the capacitor and the stack at the perimeter of the capacitor. For example, the capacitor can be similar to or the same as the resonator 100 of FIG. 1, and the membrane 502 can include some or all of the various layers and other components of the resonator 100 of FIG. 1, e.g., including at least a bottom electrode, a top electrode, and a piezoelectric layer therebetween.

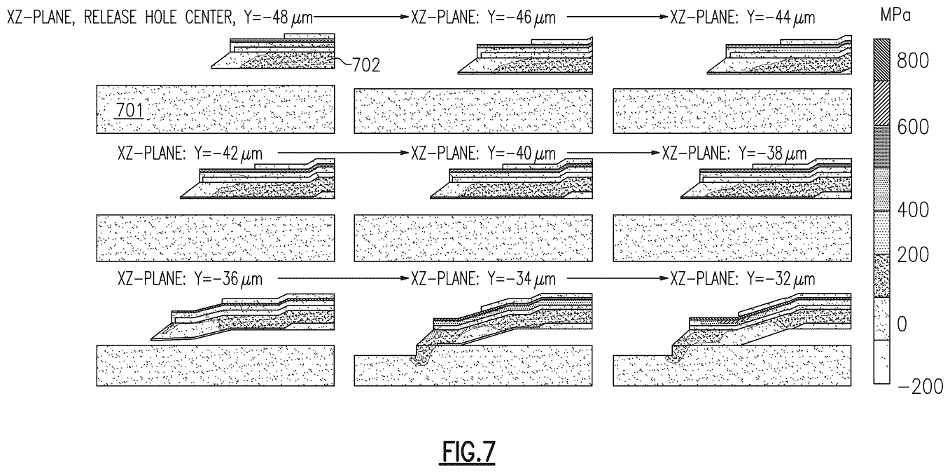

FIG. 6 illustrates the stress distribution in an xy-plane of a capacitor having an essentially or generally oval shape 600A and an essentially or generally circular shape 600B as obtained from a first principle simulation. The stress at the perimeter of the capacitor is sensitive to the shape and the columnar structure of the piezoelectric at the perimeter of the capacitor. For the essentially or generally oval shape 600A, the stress is greater on the round end than on the flatter end. A membrane of AlN can tear due to tensile stress at about 200 MPa.

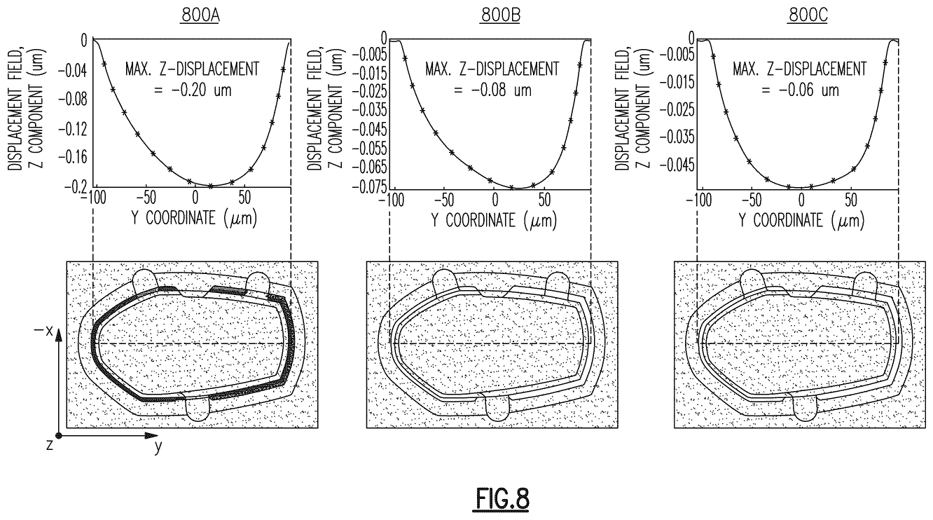

FIG. 7 illustrates the stress distribution in an xz-plane for specific values of the y coordinate of the capacitor having the essentially or generally oval shape 600A of FIG. 6. FIG. 7 illustrates that, while the stress at the perimeter of the capacitor is low in the region of the release hole, the stress is increased at portions of the perimeter of the capacitor in which the membrane 702 forms an actual connection with the substrate 701. In the example shown in FIG. 7, the membrane 702 may comprise a piezoelectric, a mean transverse energy (MTE) layer, and a metal layer, etc.

To improve the ruggedness along the capacitor's perimeter, a width of cavity may be reduced. The reduction results in an increase of the average stack thickness along the perimeter of the capacitor, essentially without modifying the deposition process for the layers of the BAW resonator stack. In other words, in an existing production process or process of records, the width of the cavity is reduced while the width of the BAW resonator stack's layers are maintained. Hence, considering a specific direction, a ratio of a partial width of a layer above a cavity, the layer forming in the partial width a connection structure with a substrate at a perimeter of the cavity, and a total width of the layer above a cavity is increased, to, e.g., a value in the range between 10 and 30%, preferably in the range between 10 and 25%, more preferably in the range between 10 and 20%, even more preferably in the range between 10 and 15%, most preferably 12%. This increase may be achieved by mere reduction of the width of the cavity in the production process, without adapting the formation of the layers above the cavity in the production process or the process of records.

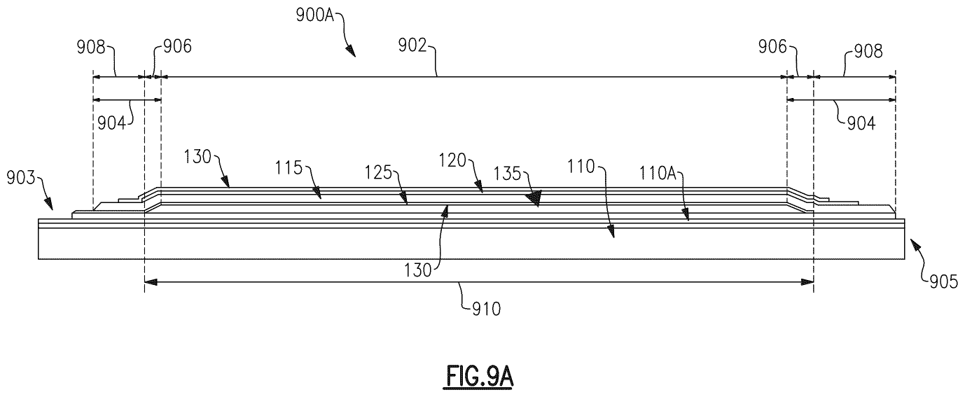

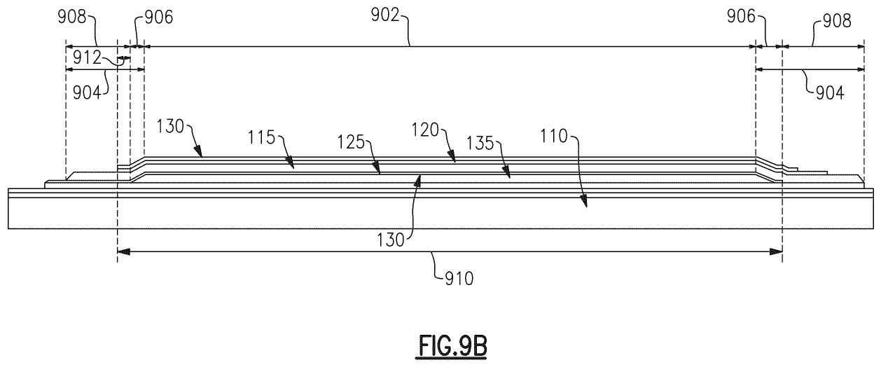

FIG. 8 illustrates the stress distribution in an xz-plane for different widths of a cavity of a capacitor having an essentially or generally oval shape and the corresponding stress distribution in a z-direction at the wafer center. The layers formed above each of the cavities shown in FIG. 8 are formed using the same production process or process of records, wherein the cavity is formed with a reduced width in the y-direction. The cavity shown under 800A has no reduced width. For example, the cavity shown under 800A may be formed similar to the resonator 100 of FIG. 1, where a region of overlap between the top and bottom electrodes does not extend across the entire mesa region of the capacitor. In contrast, a width of the cavity shown under 800B has a width that is reduced by approximately 10% with respect to the cavity shown under 800A, and a region of overlap between the top and bottom electrodes may be larger than that of the cavity shown under 800A, and may extend across at least the entire mesa region of the capacitor. Moreover, the cavity shown under 800C has a width that is reduced by approximately 15% with respect to the cavity shown under 800A. The maximal displacement in z-direction of originally 0.20 μm is reduced to 0.08 μm and 0.06 μm, respectively. Similarly, as compared to the original width of the connection structure in the y-direction at the wafer center (cf. displacement in z-direction in 800A), the width of the connection structure is increased by a value in the range between approximately 100 and 400% (cf. displacement in z-direction in 800B and 800C). The impact of the reduction of the width of the cavity on the quality factor of the capacitor is expected to be minimal. The reduction in width of the cavities and corresponding improved structural rigidity and robustness of the capacitors under 800B and 800C as compared to that under 800A may be achieved by extending the top and/or bottom electrodes further across and/or beyond the cavity, thereby increasing a region of overlap between the top and bottom electrodes, e.g., as will be described with respect to the capacitors 900A and 900B of FIGS. 9A-9B.

FIGS. 9A-9B show cross-sectional views of embodiments of capacitors 900A, 900B having improved rigidity. For example, the capacitor 900A of FIG. 9A may correspond to the capacitor 800B of FIG. 8, having a reduced cavity size as compared to the capacitor 800A of FIG. 8, and the capacitor 900B of FIG. 9B may correspond to the capacitor 800C of FIG. 8, having a further reduced cavity size as compared to the capacitor 800A of FIG. 8.

The capacitor 900A of FIG. 9A can be similar in composition to the capacitor 100 of FIG. 1, for example, with like numbered components corresponding to those of the capacitor 100 FIG. 1, including the substrate 110, dielectric surface layer 110A, bottom electrode 125, piezoelectric material 115, top electrode 120, cavity 135, and passivation layers 130. While not shown in FIG. 9A for simplicity, the capacitor 900A can include raised frame regions, recessed frame regions, and/or any of the additional layers or and other characteristics or components of the capacitor 100 of FIG. 1, depending on the embodiment.

The capacitor 900A has a piezoelectric structure including a mesa region 902 suspended above the substrate 110, with the cavity 135 being between the substrate 110 and the mesa region 902. The piezoelectric structure further includes a perimeter region 904 surrounding a perimeter of the mesa region 902. The perimeter region 904 includes a sloping portion 906 that gradually slopes towards the substrate 110. A portion of the cavity 135 is also beneath the sloping portion 906 such that the cavity 135 terminates at the point where the sloping portion 906 ends proximate the substrate 110.

The perimeter region 904 further includes a connecting portion 908 proximate the substrate 110 that supports the piezoelectric structure with respect to the substrate 110.

The piezoelectric structure includes at least the bottom electrode layer 125, the top electrode layer 120, and the piezoelectric layer 115 therebetween. While not shown in FIG. 9A, a first side 903 of the capacitor 900A can include a bottom electrode contact similar to the bottom electrode contact 140 of FIG. 1 that contacts the bottom electrode 125. Thus, the bottom electrode 125 extends on the first side 903 of the capacitor 900A beyond all of the mesa region 902, the cavity 135, the sloping portion 906, the piezoelectric layer 115, and the connecting portion 908. The bottom electrode 125 is thereby exposed to allow for connection with the bottom electrode contact.

Similarly, a second side 905 of the capacitor 900A can include a top electrode contact (not shown) similar to the top electrode contact 145 of FIG. 1 that contacts the top electrode 120. Thus, the top electrode 120 extends on the second side 905 of the capacitor 900A beyond the edge of all of the mesa region 102, the cavity 135, and the sloping portion 906, and across more than half of a width of the connecting portion 908, thereby allowing sufficient surface area for contact between the top electrode 120 and the top electrode contact.

There is an overlapping region 910 where the bottom electrode layer 125 and top electrode layer 120 overlap. The top electrode 120 and the bottom electrode 125 can act as capacitive plates and have a capacitance defined by the electrostatic constant multiplied by the area of the overlapping region 910 divided by the distance between the top electrode 120 and the bottom electrode 125. As shown, the overlapping region 910 can extend across at least a width of the mesa region 902 between opposing sides of the perimeter region 904. In the illustrated embodiment, the overlapping region 910 additionally extends beyond the mesa region 902 into at least a portion of the sloping portion 906 of the perimeter region 904, providing increased structural integrity of the piezoelectric structure.

In the illustrated embodiment, the overlapping region 910 extends across substantially the entire sloping portion 906. As shown, this is due to the extension of the bottom electrode 125 on the second side 905 of the capacitor 900A across the underside of the piezoelectric layer 115 across the entire sloping portion 906 and the extension of the top electrode 120 on the first side 903 of the capacitor 900A across the top side of the piezoelectric layer 115 across the entire sloping portion 906. In various other implementations, the overlapping region 910 extends across at least 25%, 50%, 75%, or 90% of an area or width of the sloping portion 906, or across an area or width of the sloping portion 906 between any of the foregoing amounts, or substantially across the entire area or width of the sloping portion 906. Depending on the embodiment, the bottom electrode 125 can extend on the second side 905 of the capacitor 900A across at least 10%, 25%, 50%, 75%, or 90% of an area or width of the sloping portion 906 of the perimeter region 904, or across an area or width the sloping portion 906 on the second side 905 between any of these amounts. Depending on the embodiment, the top electrode 120 can extend on the first side 903 of the capacitor 900A across at least 10%, 25%, 50%, 75%, or 90% of an area or width of the sloping portion 906 of the perimeter region 904, or across an area or width of the sloping portion 906 on the first side 903 between any of these amounts. These embodiments can be contrasted with the embodiment of FIG. 1, where, on the left side of the drawing, the top electrode 120 terminates prior to the sloping portion, and on the right side of the drawing, the bottom electrode 125 terminates prior to the sloping portion.

In the embodiment of FIG. 9A, the overlapping region 910 terminates at the connecting portion 908 on each side of the capacitor 900A. However, FIG. 9B illustrates another embodiment in which the width of the cavity 135 is further reduced and the overlapping region 910 additionally extends across at least some of the connecting portion 908 of the perimeter region 904. For example, in the illustrated embodiment, the top electrode 120 (and thus the overlapping region 910) extends into the connection portion 908 on the first side 903 of the capacitor 900B by a width 912. Depending on the embodiment, on the first side 903 of the capacitor 900B the top electrode 120 and overlapping region 910 can extend across at least 10%, 15%, 25%, 30%, or 50% of an area or width the connecting portion 908, or can extend across an area or width of the connecting portion 908 between any of these amounts. In general, the amount of overlap and/or cavity size can be selected to tune to the desired capacitance value while achieving sufficient structural integrity. In some additional embodiments, the bottom electrode 125 can extend on the second side 905 of the capacitor into the connecting portion 908 instead of terminating at the end of the sloping portion 906, thereby further increasing the size of the overlapping region 910 and the corresponding structural integrity.

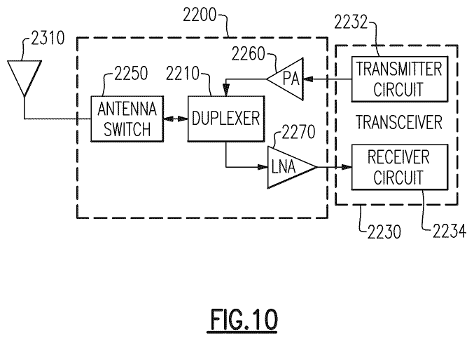

The filter 300 of FIG. 3, the BAW resonators illustrated in FIG. 1, or the capacitors illustrated in FIGS. 5 to 9B may also be included in a radio-frequency front end (RFFE) module. An exemplary RFFE module is shown in FIG. 10. This figure illustrates a front end module 2200, connected between an antenna 2310 and a transceiver 2230. The front end module 2200 includes a duplexer 2210 in communication with an antenna switch 2250, which itself is in communication with the antenna 2310.

As illustrated, the transceiver 2230 comprises a transmitter circuit 2232. Signals generated for transmission by the transmitter circuit 2232 are received by a power amplifier (PA) module 2260 within the front end module 2200 which amplifies the generated signals from the transceiver 2230. The PA module 2260 can include one or more Pas. The PA module 2260 can be used to amplify a wide variety of RF or other frequency-band transmission signals. For example, the PA module 2260 can receive an enable signal that can be used to pulse the output of the PE to aid in transmitting a wireless local area network (WLAN) signal or any other suitable pulsed signal. The PA module 2260 can be configured to amplify any of a variety of types of signal, including, for example, a Global System for Mobile (GSM) signal, a code division multiple access (CDMA) signal, a W-CDMA signal, a Long Term Evolution (LTE) signal, or an EDGE signal. In certain embodiments, the PA module 2260 and associated components including switches and the like can be fabricated on gallium arsenide (GaAs) substrates using, for example, high electron mobility transistors (pHEMT) or insulated-gate bipolar transistors (BiFET), or on a silicon substrate using complementary metal-oxide semiconductor (CMOS) field effect transistors (FETs).

The BAW resonators, capacitors and filters described herein, such as those described with respect to FIGS. 1 to 9B, may be incorporated onto one or more dies used within the module 2200. In particular, a die incorporating BAW resonators, capacitors or filters according to the present disclosure may be included in one or more filters (e.g., such as the filter 300 of FIG. 3) positioned on a separate die on the module 2200 between the antenna switch 2250 and the antenna 2310, between the antenna switch 2250 and the duplexer 220, between the duplexer 2210 and one or both of the power amplifier 2260 and the LNA 2270, between the transceiver 2230 and one or both of the power amplifier 2260 and the LNA 2270, or within a die including any of the antenna switch 2250, the duplexer 2210, the LNA 270, or the power amplifier 2260.

Still referring to FIG. 10, the front end module 2200 may further include a low noise amplifier (LNA) module 2270, which amplifies received signals from the antenna 2310 and provides the amplified signals to the receiver circuit 2234 of the transceiver 2230.

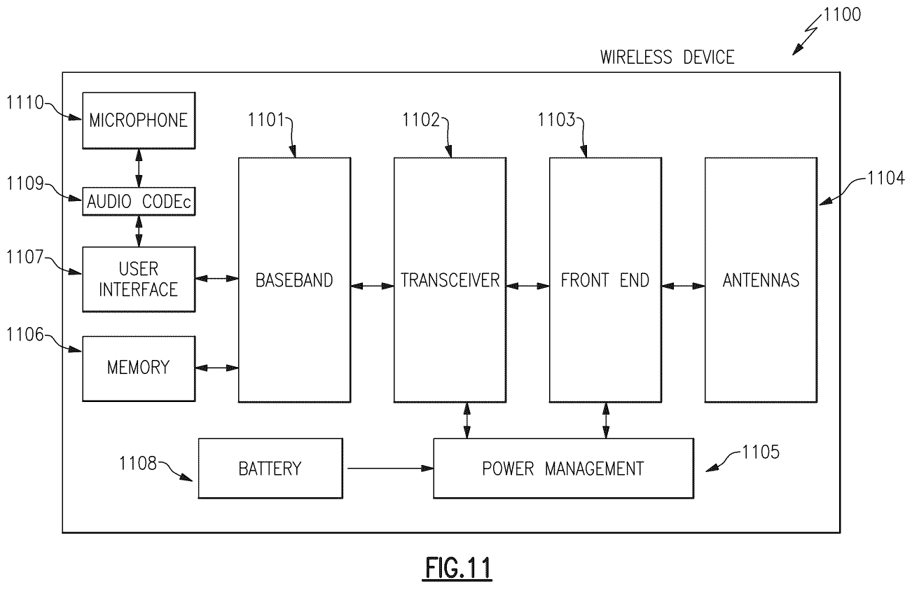

FIG. 11 is a schematic diagram of a wireless device 1100 that can incorporate aspects of the invention. The wireless device 1100 can be, for example but not limited to, a portable telecommunication device such as, a mobile cellular-type telephone. The wireless device 1100 can include a microphone arrangement 1110, and may include one or more of a baseband system 1101, a transceiver 1102, a front end system 1103 (such as the front end module 2200 of FIG. 10), one or more antennas 1104, a power management system 1105, a memory 1106, a user interface 1107, a battery 1108, and audio codec 1109. The microphone arrangement may supply signals to the audio codec 109 which may encode analog audio as digital signals or decode digital signals to analog. The audio codec 1109 may transmit the signals to a user interface 1107. The user interface 1107 transmits signals to the baseband system 1101. The transceiver 1102 generates RF signals for transmission and processes incoming RF signals received from the antennas. The front end system 1103 aids in conditioning signals transmitted to and/or received from the antennas 1104. The antennas 1104 can include antennas used for a wide variety of types of communications. For example, the antennas 1104 can include antennas 1104 for transmitting and/or receiving signals associated with a wide variety of frequencies and communications standards. The baseband system 1101 is coupled to the user interface to facilitate processing of various user input and output, such as voice and data. The baseband system 1101 provides the transceiver 1102 with digital representations of transmit signals, which the transceiver 1102 processes to generate RF signals for transmission. The baseband system 1101 also processes digital representations of received signals provided by the transceiver 1102.

As shown in FIG. 11, the baseband system 1101 is coupled to the memory 1106 to facilitate operation of the wireless device 1100. The memory 1106 can be used for a wide variety of purposes, such as storing data and/or instructions to facilitate the operation of the wireless device 1100 and/or to provide storage of user information. The power management system 1105 provides a number of power management functions of the wireless device 1100. The power management system 1105 receives a battery voltage from the battery 1108. The battery 1108 can be any suitable battery for use in the wireless device, including, for example, a lithium-ion battery.

The BAW resonators, capacitors and filters described herein, such as those described with respect to FIGS. 1 to 9B, may be incorporated onto one or more dies used within the wireless device 1100. In particular, a die incorporating BAW resonators, capacitors and filters according to the present disclosure may be incorporated into a radio-frequency module (e.g., a front end system 1103 such as radio-frequency front end module) which may be incorporated into the wireless device 1100. The BAW resonators and capacitors may be incorporated into a number of different components which may be incorporated into the wireless device 1100, including but not limited to various forms of filters and duplexers.

The piezoelectric layers of the acoustic devices described herein may have been described with respect to a specific example, though it will be appreciated that other compositions of piezoelectric layer may be used. The required piezoelectric material will be based upon, amongst other considerations, the desired frequency range of operation of the acoustic device. A non-exhaustive list of possible piezoelectric materials includes aluminum nitride (AlN), doped aluminum nitride, lithium niobate (LiNbO3), lithium tantalate (LiTaO3), lead titanate (PbTiO3), and zirconium titanate (ZrTiO3).

Similarly, a variety of materials may be used for the top and bottom electrodes in each of the embodiments described herein. Preferably, the top and bottom electrodes are formed from a material having a high acoustic impedance. The top and bottom electrodes may be formed from the same material. Suitable materials include, but are not limited to, tungsten (W), platinum (Pt), iridium (Ir), ruthenium (Ru), aluminum (Al), copper (Cu), palladium (Pd), osmium (Os), beryllium (Be), and molybdenum (Mo).

Any of the principles and advantages discussed herein can be applied to other systems, not just to the systems described above. The elements and operations of the various examples described above can be combined to provide further examples. Some of the examples described above have provided examples in connection with power amplifiers and/or wireless communications devices. However, the principles and advantages of the examples can be used in connection with any other systems, apparatus, or methods that benefit could from any of the teachings herein. For instance, any of the principles and advantages discussed herein can be implemented in connection with detecting power from one of a plurality of different signal paths of which only one is active at a time. Any of the principles and advantages discussed herein can be implemented in association with RF circuits configured to process signals in a range from about 30 kilohertz (kHz) to 300 gigahertz (GHz), such as in a range from about 450 MHz to 6 GHZ.

Aspects of this disclosure can be implemented in various electronic devices. Examples of the electronic devices can include, but are not limited to, consumer electronic products, parts of the consumer electronic products such as packaged radio frequency modules, radio frequency filter die, uplink wireless communication devices, wireless communication infrastructure, electronic test equipment, etc. Examples of the electronic devices can include, but are not limited to, a mobile phone such as a smart phone, a wearable computing device such as a smart watch or an car piece or smart eyeglasses or virtual reality equipment, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, IoT radios, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain examples include, while other examples do not include, certain features, elements and/or states. The word “coupled”, as generally used herein, refers to two or more elements that may be either directly coupled, or coupled by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain examples have been described, these examples have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions and changes in the form of the resonators, filters, multiplexer, devices, modules, wireless communication devices, apparatus, methods, and systems described herein may be made without departing from the spirit of the disclosure. For example, while blocks are presented in a given arrangement, alternative examples may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various examples described above can be combined to provide further examples. The accompanying claims and their equivalents are intended to cover such forms or modifications as would fall within the scope and spirit of the disclosure.

What is claimed is:

1. A capacitor comprising:
a substrate; and
a piezoelectric structure including a piezoelectric structure including a cavity above the substrate and a mesa region suspended above the cavity, the piezoelectric structure further including a perimeter region surrounding a perimeter of the mesa region, the perimeter region including a sloping portion that gradually slopes towards the substrate and a connecting portion proximate the substrate that supports the piezoelectric structure with respect to the substrate, the piezoelectric structure including a bottom electrode layer, a top electrode layer, and a piezoelectric layer therebetween, an overlapping region where the bottom electrode layer and the top electrode layer overlap extending across at least a width of the mesa region between opposing sides of the perimeter region.

2. The capacitor of claim 1 wherein the overlapping region further extends across at least a portion of the sloping portion of the perimeter region.

3. The capacitor of claim 2 wherein the overlapping region extends across at least 25% of the width of the sloping portion on a first side of the capacitor having a bottom electrode contact, the first side opposing a second side of the capacitor having a top electrode contact.

4. The capacitor of claim 3 wherein the overlapping region extends across an entire width of the sloping portion on the first side.

5. The capacitor of claim 2 wherein the overlapping region extends across at least a portion of a width of the connecting portion.

6. The capacitor of claim 5 wherein the overlapping region extends across an entire width of the sloping portion on a first side of the capacitor having a bottom electrode contact, the first side opposing a second side of the capacitor having a top electrode contact, and further extends across at least a portion of the connecting portion on the first side of the capacitor.

7. The capacitor of claim 2 wherein the bottom electrode layer extends under an entire area of the sloping portion.

8. The capacitor of claim 2 wherein the top electrode layer extends across at least 75% of an area of the sloping portion.

9. The capacitor of claim 8 wherein the top electrode layer extends across an entire area of the sloping portion.

10. The capacitor of claim 2 wherein the bottom electrode layer extends across at least 75% of an area of the sloping portion.

11. The capacitor of claim 2 wherein the bottom electrode layer extends across an entire area of the sloping portion.

12. The capacitor of claim 2 further comprising a silicon dioxide layer between the substrate and the piezoelectric structure.

13. A bulk acoustic wave resonator including the capacitor of claim 1.

14. A radio frequency filter comprising:
an input port and an output port; and
a plurality of bulk acoustic wave resonators connected between the input port and the output port and arranged to generate a filter response, at least one of the plurality of bulk acoustic wave resonators configured as a capacitor having a piezoelectric structure including a cavity above a substrate and a mesa region suspended above the cavity, the piezoelectric structure further including a perimeter region surrounding a perimeter of the mesa region, the perimeter region including a sloping portion that gradually slopes towards the substrate and a connecting portion proximate the substrate that supports the piezoelectric structure with respect to the substrate, the piezoelectric structure including a bottom electrode layer, a top electrode layer, and a piezoelectric layer therebetween, an overlapping region where the bottom electrode layer and the top electrode layer overlap extending across at least a width of the mesa region between opposing sides of the perimeter region.

15. The capacitor of claim 14 wherein the overlapping region extends across at least 25% of the width of the sloping portion on a first side of the capacitor having a bottom electrode contact, the first side opposing a second side of the capacitor having a top electrode contact.

16. The capacitor of claim 15 wherein the overlapping region extends across an entire width of the sloping portion on the first side.

17. The capacitor of claim 14 wherein the overlapping region extends across at least a portion of a width of the connecting portion.

18. The capacitor of claim 14 wherein the overlapping region extends across an entire width of the sloping portion on a first side of the capacitor having a bottom electrode contact, the first side opposing a second side of the capacitor having a top electrode contact, and further extends across at least a portion of the connecting portion on the first side of the capacitor.

19. A radio frequency module comprising:
one or more amplifiers configured to amplify a radio frequency signal; and
a radio frequency filter including a plurality of bulk acoustic wave resonators, at least one of the plurality of bulk acoustic wave resonators configured as a capacitor having a piezoelectric structure including a cavity above a substrate and a mesa region suspended above the cavity, the piezoelectric structure further including a perimeter region surrounding a perimeter of the mesa region, the perimeter region including a sloping portion that gradually slopes towards the substrate and a connecting portion proximate the substrate that supports the piezoelectric structure with respect to the substrate, the piezoelectric structure including a bottom electrode layer, a top electrode layer, and a piezoelectric layer therebetween, an overlapping region where the bottom electrode layer and the top electrode layer overlap extending across at least a width of the mesa region between opposing sides of the perimeter region.

20. A wireless device including the radio frequency module of claim 19.
